(19) United States
(12) Patent Application Publication
(10) Pub. No.: US 2013/0069698 A1
(43) Pub. Date: Mar. 21, 2013

(54) RESET SIGNAL GENERATING CIRCUIT AND SEMICONDUCTOR INTEGRATED CIRCUIT INCLUDING THE SAME

(71) Applicant: Masaya FUKAZAWA, Kanagawa (JP)

(72) Inventor: Masaya FUKAZAWA, Kanagawa (JP)

(73) Assignee: RENESAS ELECTRONICS CORPORATION, Kawasaki-shi (JP)

(21) Appl. No.: 13/619,094

(22) Filed: Sep. 14, 2012

(30) Foreign Application Priority Data
Sep. 16, 2011 (JP) 2011-203481

(51) Int. Cl. H03L 9/00

(52) U.S. Cl. 327/142

(57) ABSTRACT

A reset signal generating circuit according to an aspect of the present invention includes: a first signal line that transmits a reference reset signal to a first node; a second signal line that transmits an inverted signal of the reference reset signal to a second node; a first inverting circuit that outputs an inverter signal of the signal transmitted to the second node; and a control circuit that makes a reset signal active regardless of the reference reset signal, when a logical value of the signal transmitted to the first node does not match a logical value of the signal output from the first inverting circuit.

### CROSS-REFERENCE TO RELATED APPLICATIONS

This application is based upon and claims the benefit of priority from Japanese patent application No. 2011-203481, filed on Sep. 16, 2011, the disclosure of which is incorporated herein in its entirety by reference.

### BACKGROUND

The present invention relates to a reset signal generating circuit and a semiconductor integrated circuit including the same.

In recent years, a large number of LSIs (Large Scale Integrations) are used for automobiles. These LSIs are required to operate so as to maintain the safety of automobiles even if a fault occurs.

For this reason, the LSIs adopt a redundant circuit configuration in which two circuits having the same configuration are provided, for example. This redundant circuit configuration enables detection of accidental malfunction occurring in one circuit due to noise or the like, by comparing the operation of one circuit with the operation of the other circuit.

Japanese Unexamined Patent Application Publication No. 01-261948 discloses a related art (see FIGS. 10 and 11).

As shown in FIG. 10, in a network system according to the related art, a network controller 501 and a plurality of nodes 502 are each connected to a serial data transmission path 503, and a hardware reset line 504 is connected to the plurality of nodes 502. A reset signal 505 of the network controller 501 is output to the hardware reset line 504 through an output unit 506. Input units 507, which are provided in the respective nodes 502, receive the reset signal 505 transmitted through the hardware reset line 504.

As shown in FIG. 11, a twisted pair line including a signal line 541 and a signal line 542 is used as the hardware reset line 504. Balanced differential type elements are used as the output unit 506 and the input units 507. A terminating resistor 508 is provided at a terminal of the hardware reset line 504. This improves the resistance to noise in the hardware reset line 504 as disclosed in Japanese Unexamined Patent Application Publication No. 01-261948.

### SUMMARY

Incidentally, the inventor of the present invention has found that the hardware reset line 504 and peripheral circuits of the related art generally operate as shown in FIGS. 12A to 12F. FIGS. 12A to 12F are timing diagram each showing the operation of the related art. For ease of explanation, the following description is given assuming that the amplitude of the reset signal (hereinafter referred to as “reference reset signal”, for convenience of explanation) 505 ranges from 0 V (L level) to 1.5 V (H level); a power supply voltage for divining the output unit 506 and each input unit 507 is 1.5 V; and the output voltage of each input unit 507 ranges from 0 V (L level) to 1.5 V (H level). The reference reset signal 505 becomes active (reset state) at L level and becomes inactive (reset state is released) at H level.

FIG. 12A is a timing diagram showing a normal operation of the related art. As shown in FIG. 12A, when the reference reset signal 505 is at L level, the output unit 506 outputs an L-level signal to the signal line 541, and outputs an H-level signal, which is an inverted signal, to the signal line 542. Each input unit 507 receives the L-level signal through the signal line 541, and also receives the H-level signal through the signal line 542. In this case, each input unit 507 outputs a signal (referred to as “reset signal”, for convenience of explanation) according to a voltage difference between the signal lines 541 and 542. Specifically, each input unit 507 outputs the H-level reset signal when the voltage level of the signal line 541 is equal to or higher than the voltage level of the signal line 542, and outputs the L-level reset signal in the other cases. Therefore, in this case, each input unit 507 outputs the L-level reset signal. That is, each input unit 507 makes the reset signal active (reset state). On the other hand, when the reference reset signal 505 is at H level, the output unit 506 outputs the H-level signal to the signal line 541, and outputs the L-level signal, which is an inverted signal, to the signal line 542. Each input unit 507 receives the H-level signal transmitted through the signal line 541, and also receives the L-level signal transmitted through the signal line 542. In this case, each input unit 507 outputs the H-level reset signal. That is, each input unit 507 makes the reset signal inactive (reset state is released).

FIG. 12B is a timing diagram showing the operation of the related art when common noise occurs. As described above, each input unit 507 outputs the reset signal according to the voltage difference between the signal lines 541 and 542. Accordingly, as shown in FIG. 12B, even if common noise occurs in the signal lines 541 and 542, the common noise is cancelled by each input unit 507. As a result, each input unit 507 outputs the reset signal having the same logical value as that of the reference reset signal 505.

FIG. 12C is a timing diagram showing the operation of the related art when a fault (stuck-at-0 fault) occurs in which the signal level of the signal line 541 is fixed to the L level. As shown in FIG. 12C, even if the stuck-at-0 fault occurs in the signal line 541, each input unit 507 outputs the reset signal having the same logical value as that of the reference reset signal 505 based on the voltage difference between the signal lines 541 and 542.

FIG. 12D is a timing diagram showing the operation of the related art when a fault (stuck-at-1 fault) occurs in which the signal level of the signal line 542 is fixed to the H level. As shown in FIG. 12D, even if the stuck-at-1 fault occurs in the signal line 542, each input unit 507 outputs the reset signal having the same logical value as that of the reference reset signal 505 based on the voltage difference between the signal lines 541 and 542.

FIG. 12E is a timing diagram showing the operation of the related art when a stuck-at-1 fault occurs in the signal line 541. As shown in FIG. 12E, if the stuck-at-1 fault occurs in the signal line 541, each input unit 507 constantly outputs the H-level reset signal based on the voltage difference between the signal lines 541 and 542. That is, each input unit 507 unintentionally makes the reset signal inactive (reset state is released).

FIG. 12F is a timing diagram showing the operation of the related art when a stuck-at-0 fault occurs in the signal line 542. As shown in FIG. 12F, if the stuck-at-0 fault occurs in the signal line 542, each input unit 507 constantly outputs the H-level reset signal based on the voltage difference between the signal lines 541 and 542. That is, each input unit 507 unintentionally makes the reset signal inactive (reset state is released).

In this manner, the configuration of the related art has a problem that when a stuck-at fault occurs in at least one of the signal lines 541 and 542, the reset signal is unintentionally made inactive, that is, the reset state is unintentionally released. This may cause malfunction in the circuit, the initialization of which is controlled by the reset signal.

A first aspect of the present invention is a reset signal generating circuit including: a first signal line that transmits a reference reset signal to a first node; a second signal line that transmits an inverted signal of the reference reset signal to a second node; a first inverting circuit that outputs the inverted signal of the signal transmitted to the second node; and a control circuit that makes a reset signal active regardless of the reference reset signal, when a logical value of the signal transmitted to the first node does not match a logical value of the signal output from the first inverting circuit.

The circuit configuration as described above prevents unintentional releasing of the reset signal due to noise, a stuck-at fault, or the like.

According to an aspect of the present invention, it is possible to provide a reset signal generating circuit capable of preventing unintentional releasing of a reset signal due to noise, a stuck-at fault, or the like, and a semiconductor integrated circuit including the reset signal generating circuit.

### BRIEF DESCRIPTION OF THE DRAWINGS

The above and other aspects, advantages and features will be more apparent from the following description of certain embodiments taken in conjunction with the accompanying drawings, in which:

FIG. 1 is a diagram showing a configuration example of a reset signal generating circuit according to a first embodiment of the present invention;

FIG. 2 is a diagram showing another configuration example of the reset signal generating circuit according to the first embodiment of the present invention;

FIG. 3 is still another configuration example of the reset signal generating circuit according to the first embodiment of the present invention;

FIG. 4 is further another configuration example of the reset signal generating circuit according to the first embodiment of the present invention;

FIG. 5 is further another configuration example of the reset signal generating circuit according to the first embodiment of the present invention;

FIG. 6A is a timing diagram showing operation of the reset signal generating circuit according to the first embodiment of the present invention;

FIG. 6B is a timing diagram showing operation of the reset signal generating circuit according to the first embodiment of the present invention;

FIG. 6C is a timing diagram showing operation of the reset signal generating circuit according to the first embodiment of the present invention;

FIG. 6D is a timing diagram showing operation of the reset signal generating circuit according to the first embodiment of the present invention;

FIG. 6E is a timing diagram showing operation of the reset signal generating circuit according to the first embodiment of the present invention;

FIG. 6F is a timing diagram showing operation of the reset signal generating circuit according to the first embodiment of the present invention;

FIG. 7 is a diagram showing a configuration example of a reset signal generating circuit according to a second embodiment of the present invention;

FIG. 8A is a timing diagram showing operation of the reset signal generating circuit according to the second embodiment of the present invention;

FIG. 8B is a timing diagram showing operation of the reset signal generating circuit according to the second embodiment of the present invention;

FIG. 8C is a timing diagram showing operation of the reset signal generating circuit according to the second embodiment of the present invention;

FIG. 8D is a timing diagram showing operation of the reset signal generating circuit according to the second embodiment of the present invention;

FIG. 8E is a timing diagram showing operation of the reset signal generating circuit according to the second embodiment of the present invention;

FIG. 8F is a timing diagram showing operation of the reset signal generating circuit according to the second embodiment of the present invention;

FIG. 9 is a diagram showing a configuration example of a semiconductor integrated circuit according to a third embodiment of the present invention;

FIG. 10 is a timing diagram showing operation of a related art;

FIG. 11 is a diagram showing operation of the related art;

FIG. 12A is a timing diagram showing operation of the related art;

FIG. 12B is a timing diagram showing operation of the related art;

FIG. 12C is a timing diagram showing operation of the related art;

FIG. 12D is a timing diagram showing operation of the related art;

FIG. 12E is a timing diagram showing operation of the related art; and

FIG. 12F is a timing diagram showing operation of the related art.

### DETAILED DESCRIPTION

Hereinafter, embodiments of the present invention will be described with reference to the drawings. Note that the drawings are in simplified form, and the technical scope of the present invention should not be interpreted to be limited to the drawings. The same elements are denoted by the same reference numerals, and a repeated explanation thereof is omitted.

### First Embodiment

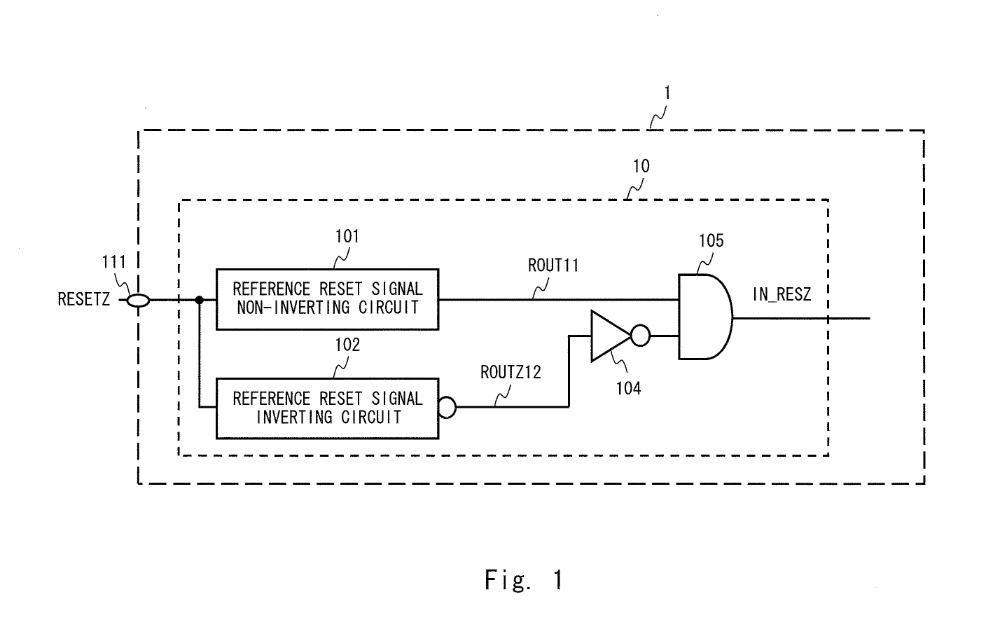

FIG. 1 is a diagram showing a configuration example of a reset signal generating circuit 10 according to a first embodiment of the present invention. The reset signal generating circuit 10 according to the first embodiment includes a plurality of signal lines for transmitting a reference reset signal. When the logical values of the signals respectively transmitted through the signal lines do not match, the reset signal generating circuit 10 makes a reset signal active (reset state) regardless of the reference reset signal. This configuration enables the reset signal generating circuit 10 according to the first embodiment to prevent the reset signal from being unintentionally released due to noise or a stuck-at fault. This configuration will be described in detail below.

As shown in FIG. 1, the reset signal generating circuit 10 is provided in a semiconductor chip (semiconductor integrated circuit) 1, and includes a reference reset signal non-inverting circuit 101, a reference reset signal inverting circuit (third inverting circuit) 102, an inverting circuit (first inverting circuit; hereinafter referred to as “INV circuit”) 104, and a control circuit 105. In the first embodiment, the case where the control circuit 105 is an AND circuit (hereinafter referred to as “AND circuit 105”) is described by way of example.

An input terminal of the reference reset signal non-inverting circuit 101 and an input terminal of the reference reset signal inverting circuit 102 are each connected to an external reset terminal 111 of the semiconductor chip 1. An output terminal of the reference reset signal non-inverting circuit 101 and a first input terminal (first node) of the AND circuit 105 are connected to each other via a signal line (first signal line) ROUT11. An output terminal of the reference reset signal inverting circuit 102 and an input terminal (second node) of the INV circuit 104 are connected to each other via a signal line (second signal line) ROUTZ12. An output terminal of the INV circuit 104 is connected to a second input terminal of the AND circuit 105. The AND circuit 105 outputs the logical product of the signals received at both input terminals as a reset signal IN_RESZ. This reset signal IN_RESZ is supplied to an internal circuit provided in the semiconductor chip 1, for example. The initialization of this internal circuit is controlled by the reset signal IN_RESZ.

Note that, for convenience of explanation, a signal propagating through the signal line ROUT11 is also referred to as a signal ROUT11, and a signal propagating through the signal line ROUTZ12 is also referred to as a signal ROUTZ12.

A reference reset signal generating circuit (not shown in FIG. 1) that generates a reference reset signal RESETZ is provided outside the semiconductor chip 1. The reference reset signal RESETZ generated outside the semiconductor chip 1 is supplied to the external reset terminal 111 of the semiconductor chip 1.

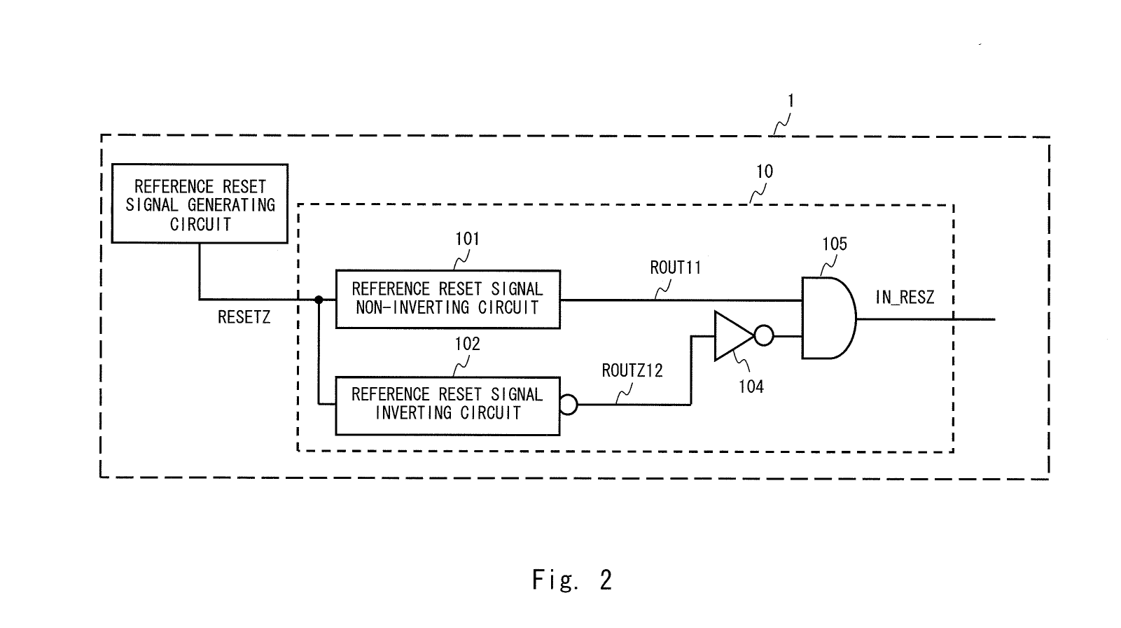

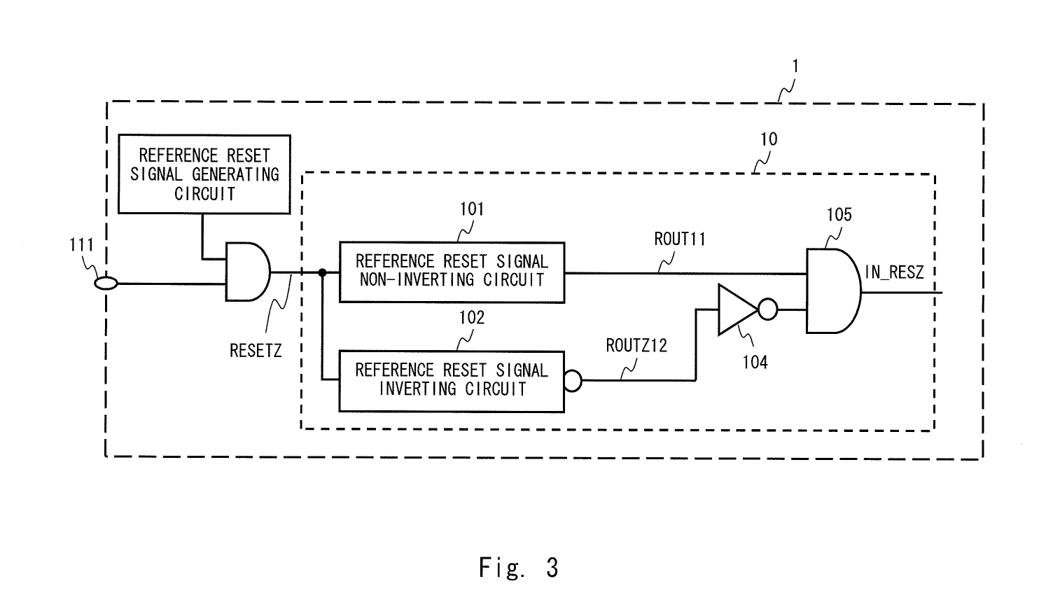

The first embodiment describes, by way of example, the case where the reference reset signal generating circuit is provided outside the semiconductor chip 1, but the present invention is not limited thereto. As shown in FIG. 2, the reference reset signal generating circuit may be provided in the semiconductor chip 1. Examples of the reference reset signal generating circuit provided in the chip include a power-on reset circuit. As shown in FIG. 3, it is also possible to employ a configuration in which a first reference reset signal generating circuit that generates a first reference reset signal is provided outside the chip; a second reference reset signal generating circuit that generates a second reference reset signal is provided in the chip; and the reference reset signal RESETZ is generated based on the first and second reference reset signals. These also hold true for other embodiments described below.

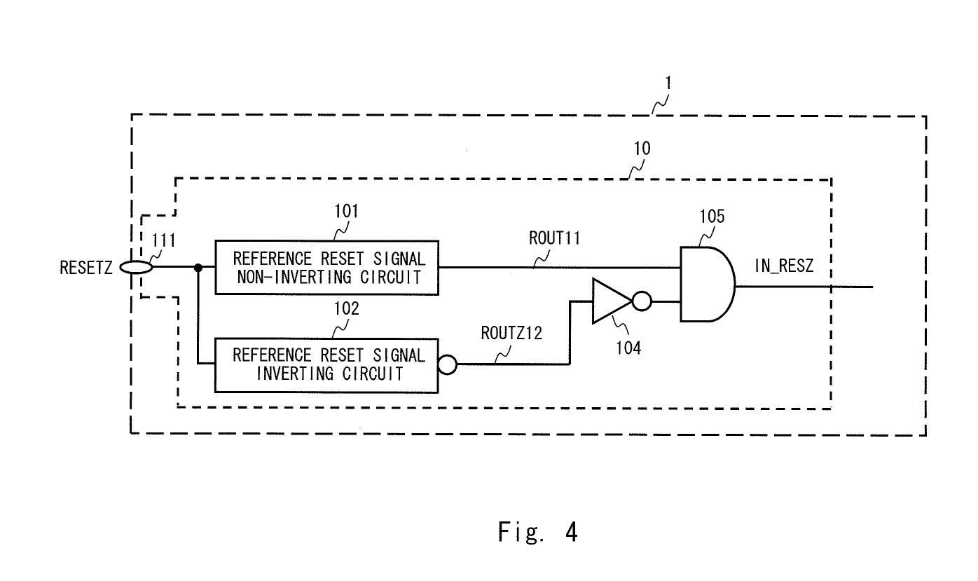

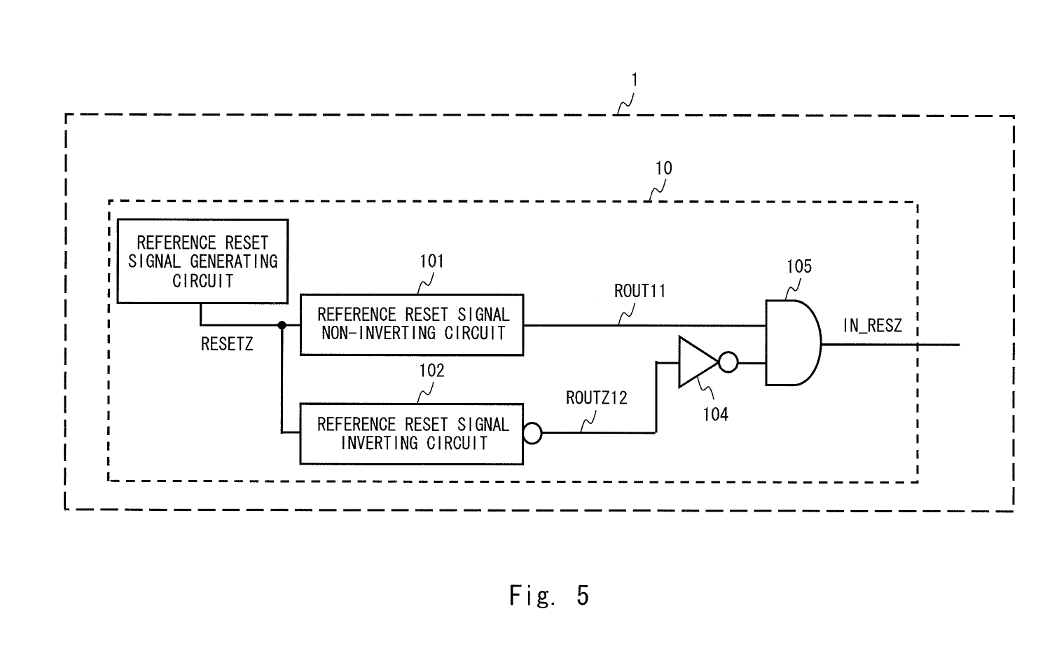

The reset signal generating circuit 10 may have a configuration including the external reset terminal 111 as shown in FIG. 4, or may have a configuration including the reference reset signal generating circuit in the chip as shown in FIG. 5. This also holds true for other embodiments described below.

The reference reset signal non-inverting circuit 101 non-inverts the reference reset signal RESETZ and outputs the non-inverted signal. In other words, the reference reset signal non-inverting circuit 101 directly outputs the reference reset signal RESETZ. The signal line ROUT11 transmits the output signal of the reference reset signal non-inverting circuit 101 to the first input terminal (first node) of the AND circuit 105.

The reference reset signal inverting circuit 102 inverts the reference reset signal RESETZ and outputs the inverted signal. The signal line ROUTZ12 transmits the output signal of the reference reset signal inverting circuit 102 to the input terminal (second node) of the INV circuit 104. The INV circuit 104 inverts the signal transmitted through the signal line ROUTZ12, and outputs the inverted signal to the second input terminal of the AND circuit 105.

As described above, the AND circuit 105 outputs the logical product of the signals received at both input terminals as the reset signal IN_RESZ.

(Timing Diagram)

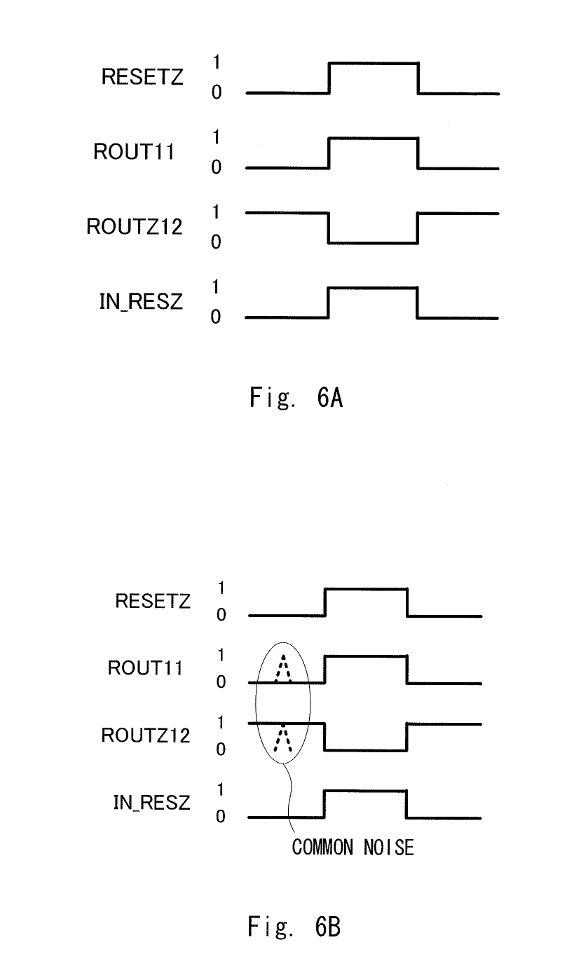

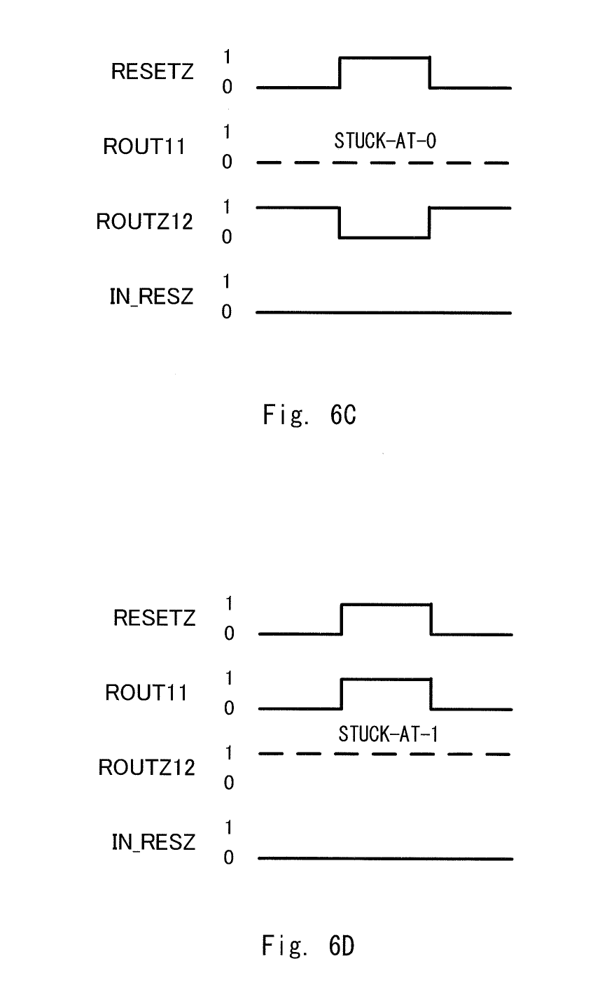

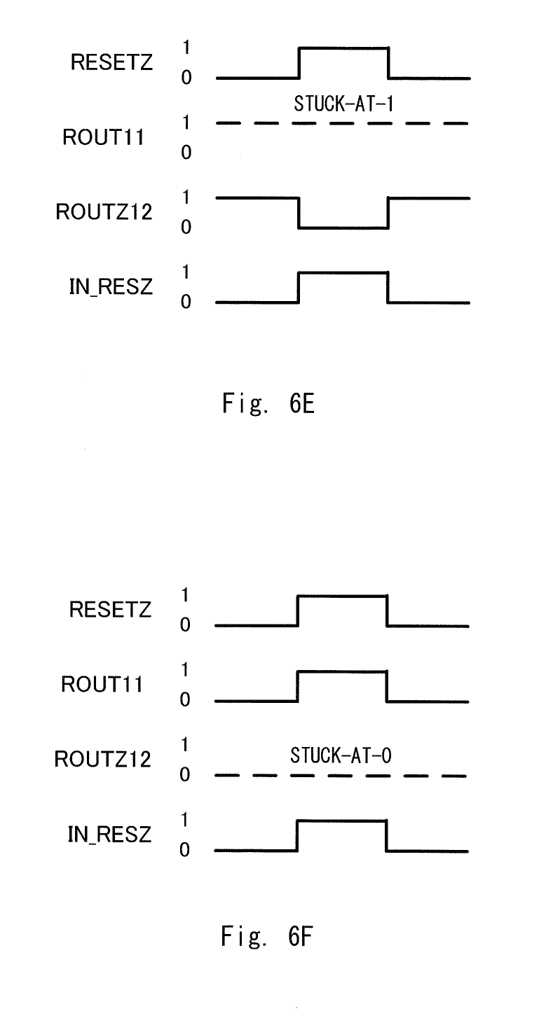

Next, the operation of the reset signal generating circuit 10 shown in FIG. 1 will be described with reference to FIGS. 6A to 6F. FIGS. 6A to 6F are timing diagrams each showing the operation of the reset signal generating circuit 10. Assume that the reset signal IN_RESZ becomes active (reset state) at L level (logical value 0) and becomes inactive (reset state is released) at H level (logical value 1).

FIG. 6A is a timing diagram showing a normal operation of the reset signal generating circuit 10. As shown in FIG. 6A, when the reference reset signal RESETZ is at L level, the signal ROUT11 indicates the L level and the signal ROUTZ12 indicates the H level representing an inverted value. The output signal of the INV circuit 104 indicates the L level. Because both input terminals of the AND circuit 105 receive the L-level signal, the AND circuit 105 outputs the L-level reset signal IN_RESZ. That is, the AND circuit 105 makes the reset signal IN_RESZ active (reset state). On the other hand, when the reference reset signal RESETZ is at H level, the signal ROUT11 indicates the H level, and the signal ROUTZ12 indicates the L level. The output signal of the INV circuit 104 indicates the H level. Because both input terminals of the AND circuit 105 receive the H-level signal, the AND circuit 105 outputs the H-level reset signal IN_RESZ. That is, the AND circuit 105 makes the reset signal IN_RESZ inactive (releases the reset state).

In this manner, when the logical values of the signals received at both input terminals match, the AND circuit 105 outputs the reset signal IN_RESZ having the logical value.

FIG. 6B is a timing diagram showing the operation of the reset signal generating circuit 10 when common noise occurs. For example, if common noise occurs in the signal lines ROUT11 and ROUTZ12 when the reference reset signal RESETZ is at L level, the signal ROUT11 fluctuates to the H-level side. On the other hand, the signal ROUTZ12 is maintained at H level. The output signal of the INV circuit 104 indicates the L level. The first input terminal of the AND circuit 105 receives the H-level signal, and the second terminal of the AND circuit 105 receives the L-level signal. Accordingly, the AND circuit 105 continuously outputs the L-level reset signal IN_RESZ. That is, the AND circuit 105 continuously makes the reset signal IN_RESZ active.

Though not shown in the figure, if common noise occurs in the signal lines ROUT11 and ROUTZ12 when the reference reset signal RESETZ is at H level, the first input terminal of the AND circuit 105 receives the H-level signal, and the second input terminal of the AND circuit 105 receives the L-level signal. Accordingly, the AND circuit 105 outputs the L-level reset signal IN_RESZ. That is, the AND circuit 105 makes the reset signal IN_RESZ active.

In this manner, when the logical values of the signals received at both input terminals do not match due to the effect of common noise, the AND circuit 105 makes the reset signal IN_RESZ active regardless of the reference reset signal RESETZ.

FIG. 6C is a timing diagram showing operation of the reset signal generating circuit 10 when a stuck-at-0 fault occurs in the signal line ROUT11. In this case, the signal ROUT11 is fixed to the L level due to the stuck-at-0 fault, so that the AND circuit 105 constantly outputs the L-level reset signal IN_RESZ.

More specifically, when the reference reset signal RESETZ is at L level, the signal ROUTZ12 indicates the H level. Accordingly, the output signal of the INV circuit 104 indicates the L level. At this time, the signal ROUT11 is fixed to the L level due to the stuck-at-0 fault. Because the logical values of the signals received at both input terminals match, the AND circuit 105 outputs the reset signal IN_RESZ having the logical value (L level). On the other hand, when the reference reset signal RESETZ is at H level, the signal ROUTZ12 indicates the L level. Accordingly, the output signal of the INV circuit 104 indicates the H level. At this time, the signal ROUT11 is fixed to the L level due to the stuck-at-0 fault. Because the logical values of the signals received at both input terminals do not match, the AND circuit 105 makes the reset signal IN_RESZ active. In short, the AND circuit 105 constantly outputs the L-level reset signal IN_RESZ.

In this manner, when the logical values received at both input terminals do not match due to the stuck-at-0 fault of the signal line ROUT11, the AND circuit 105 makes the reset signal IN_RESZ active regardless of the reference reset signal RESETZ.

FIG. 6D is a timing diagram showing the operation of the reset signal generating circuit 10 when a stuck-at-1 fault occurs in the signal line ROUTZ12. In this case, the signal ROUTZ12 is fixed to the H level due to the stuck-at-1 fault, so that the output signal of the INV circuit 104 is fixed to the L level. Therefore, the AND circuit 105 constantly outputs the L-level reset signal IN_RESZ.

More specifically, when the reference reset signal RESETZ is at L level, the signal ROUT11 indicates the L level. At this time, the signal ROUTZ12 is fixed to the H level due to the stuck-at-1 fault, so that the output signal of the INV circuit 104 is fixed to the L level. Because the logical values of the signals received at both input terminals match, the AND circuit 105 outputs the reset signal IN_RESZ having the logical value (L level). On the other hand, when the reference reset signal RESETZ is at H level, the signal ROUT11 indicates the H level. At this time, the signal ROUTZ12 is fixed to the H level due to the stuck-at-1 fault, so that the output signal of the INV circuit 104 is fixed to the L level. Because the logical values of the signals received at both input terminals do not match, the AND circuit 105 makes the reset signal IN_RESZ active. In short, the AND circuit 105 constantly outputs the L-level reset signal IN_RESZ.

In this manner, when the logical values of the signals received at both input terminals do not match due to the stuck-at-1 fault of the signal line ROUTZ12, the AND circuit 105 makes the reset signal IN_RESZ active regardless of the reference reset signal RESETZ.

FIG. 6E is a timing diagram showing the operation of the reset signal generating circuit 10 when a stuck-at-1 fault occurs in the signal line ROUT11. For example, when the reference reset signal RESETZ is at L level, the signal ROUTZ12 indicates the H level. Accordingly, the output signal of the INV circuit 104 indicates the L level. At this time, the signal ROUT11 is fixed to the H level due to the stuck-at-1 fault. Because the logical values of the signals received at both input terminals do not match, the AND circuit 105 makes the reset signal IN_RESZ active. As a result, the AND circuit 105 outputs the reset signal IN_RESZ having the same logical value as that of the reference reset signal RESETZ. On the other hand, when the reference reset signal RESETZ is at H level, the signal ROUTZ12 indicates the L level. Accordingly, the output signal of the INV circuit 104 indicates the H level. At this time, the signal ROUT11 is fixed to the H level due to the stuck-at-1 fault. Because the logical values of the signals received at both input terminals match, the AND circuit 105 outputs the reset signal IN_RESZ having the logical value (H level). In short, the AND circuit 105 constantly outputs the reset signal IN_RESZ having the same logical value as that of the reference reset signal RESETZ.

In this manner, when the logical values of the signals received at both input terminals do not match due to the stuck-at-1 fault of the signal line ROUT11, the AND circuit 105 makes the reset signal IN_RESZ active regardless of the reference reset signal RESETZ.

FIG. 6F is a timing diagram showing the operation of the reset signal generating circuit 10 when a stuck-at-0 fault occurs in the signal line ROUTZ12. For example, when the reference reset signal RESETZ is at L level, the signal ROUT11 indicates the L level. At this time, the signal ROUTZ12 is fixed to the L level due to the stuck-at-0 fault, so that the output signal of the INV circuit 104 is fixed to the H level. Because the logical values of the signals received at both input terminals do not match, the AND circuit 105 makes the reset signal IN_RESZ active. As a result, the AND circuit 105 outputs the reset signal IN_RESZ having the same logical value as that of the reference reset signal RESETZ. On the other hand, when the reference reset signal RESETZ is at H level, the signal ROUT11 indicates the H level. At this time, the signal ROUTZ12 is fixed to the L level due to the stuck-at-0 fault, so that the output signal of the INV circuit 104 is fixed to the H level. Because the logical values of the signals received at both input terminals match, the AND circuit 105 outputs the reset signal IN_RESZ having the logical value (H level). In short, the AND circuit 105 constantly outputs the reset signal IN_RESZ having the same logical value as that of the reference reset signal RESETZ.

In this manner, when the logical values of the signals received at both input terminals do not match due to the stuck-at-0 fault of the signal line ROUTZ12, the AND circuit 105 makes the reset signal IN_RESZ active regardless of the reference reset signal RESETZ.

As described above, when the logical value of the signal transmitted through the signal line ROUT11 does not match the inverted value of the signal transmitted through the signal line ROUTZ12, the reset signal generating circuit 10 according to the first embodiment makes the reset signal IN_RESZ active (reset state) regardless of the reference reset signal RESETZ. This enables the reset signal generating circuit 10 according to the first embodiment to prevent unintentional releasing of the reset signal IN_RESZ due to noise, a stuck-at fault, or the like. As a result, it is possible to prevent malfunction from occurring in the circuit, the initialization of which is controlled by the reset signal IN_RESZ.

### Second Embodiment

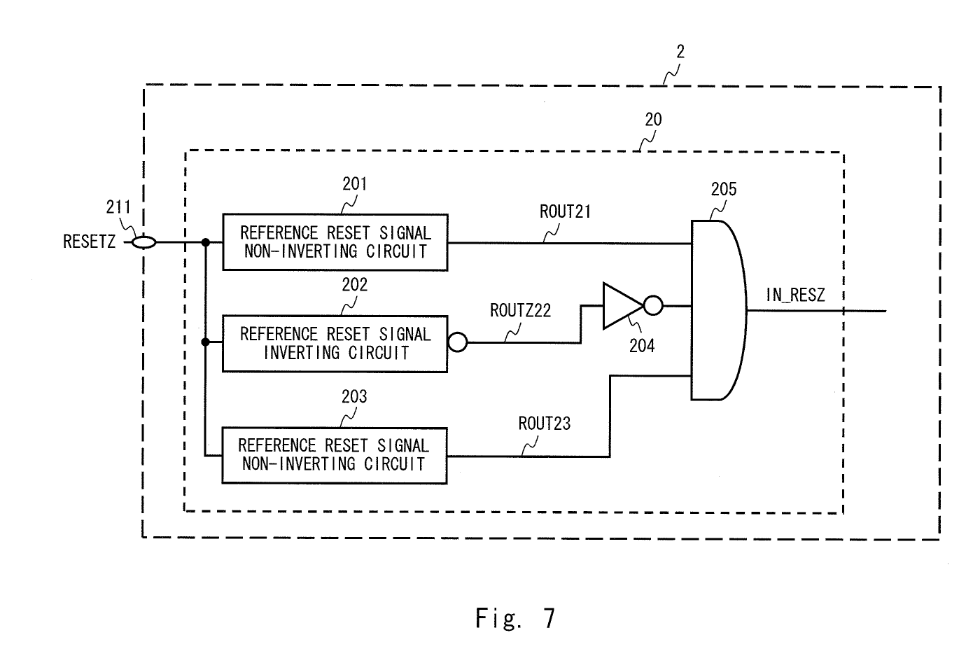

FIG. 7 is a diagram showing a configuration example of a reset signal generating circuit 20 according to a second embodiment of the present invention. In the reset signal generating circuit 20 shown in FIG. 7, an additional signal line for transmitting the reference reset signal RESETZ is provided, as compared with the reset signal generating circuit 10 shown in FIG. 1. This configuration will be described in detail below.

As shown in FIG. 7, the reset signal generating circuit 20 is provided in a semiconductor chip (semiconductor integrated circuit) 2, and includes reference reset signal non-inverting circuits 201 and 203, a reference reset signal inverting circuit 202, an INV circuit 204, and a control circuit 205. The second embodiment describes, by way of example, the case where the control circuit 205 is an AND circuit (hereinafter referred to as “AND circuit 205”).

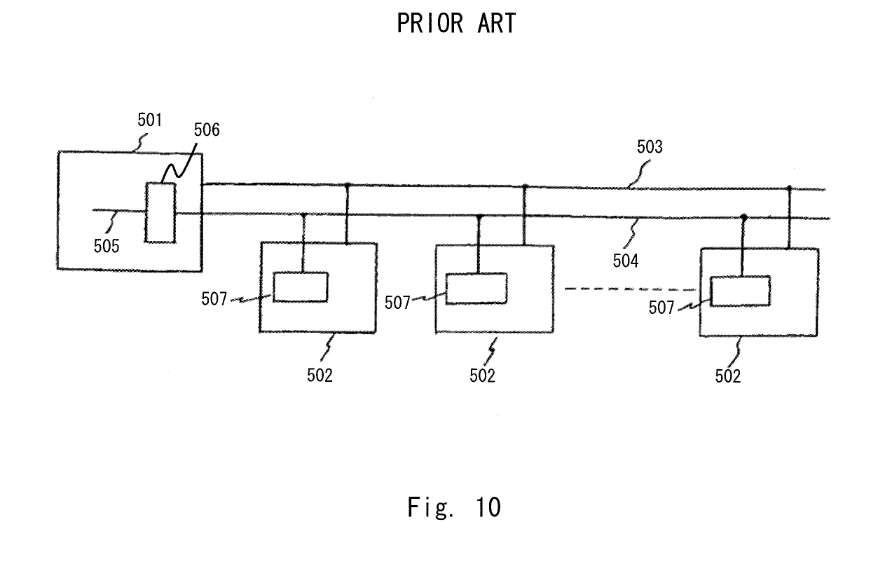

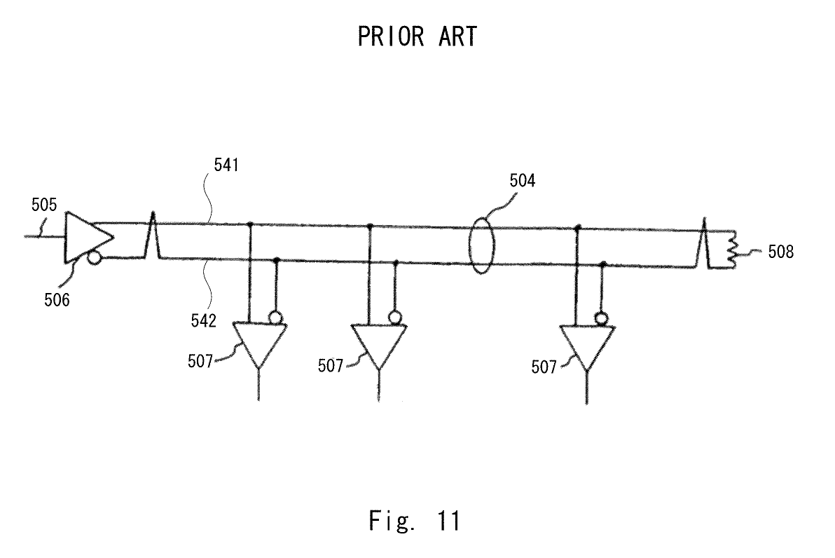

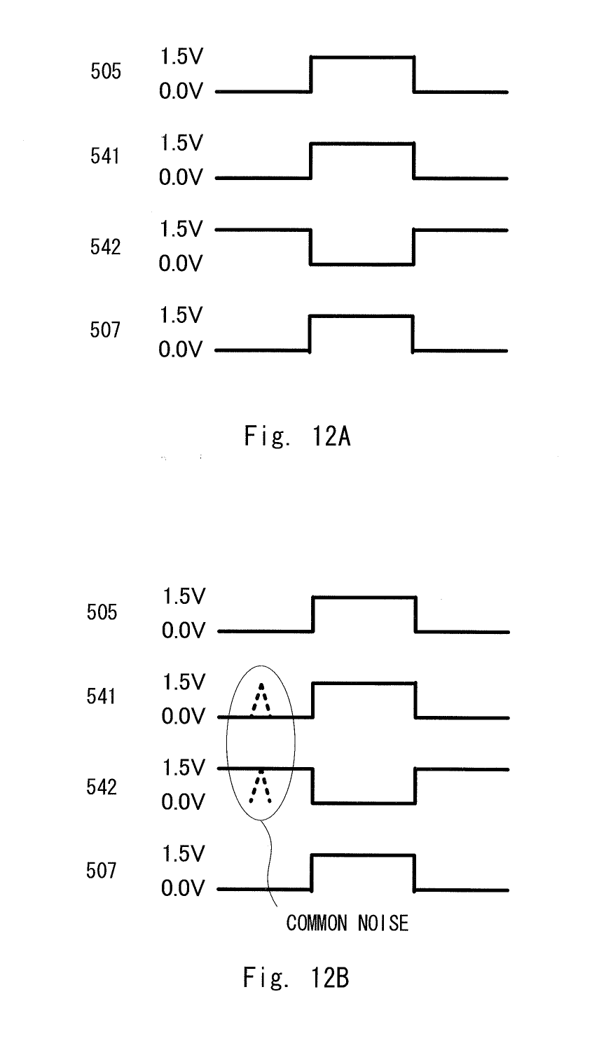

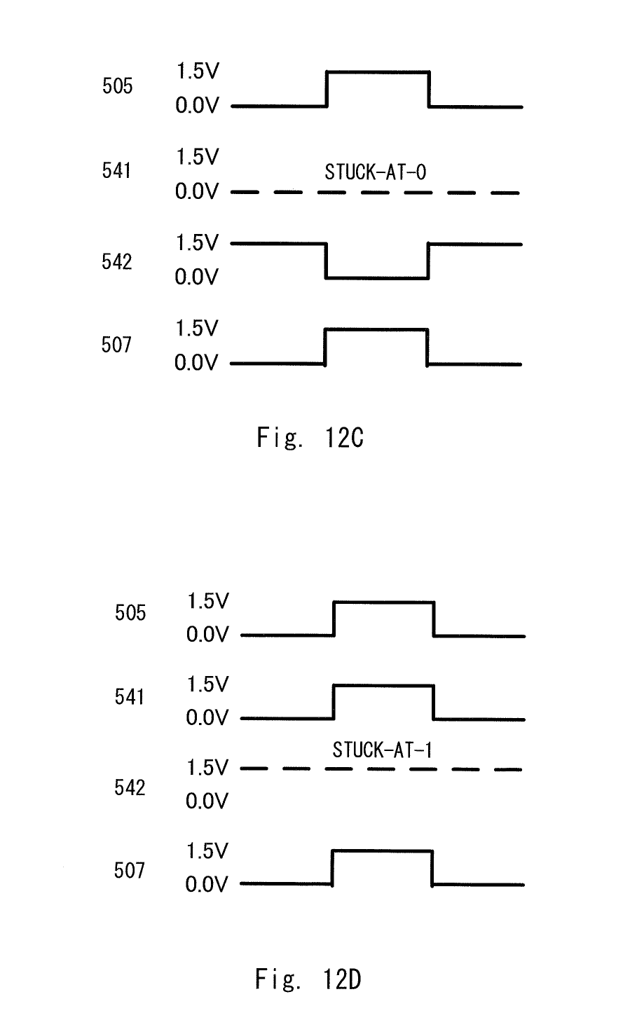

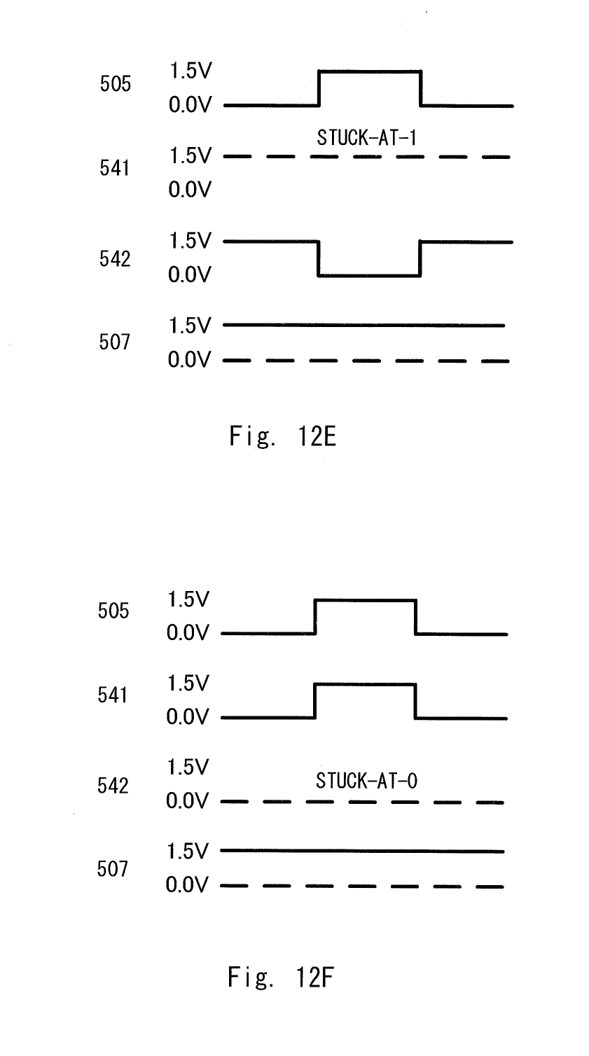

The configuration of the reset signal generating circuit 20 shown in FIG. 7 is the same as the configuration of the reset signal generating circuit 10 shown in FIG. 10 except that an additional signal line for transmitting the reference reset signal RESETZ is provided. That is, the reference reset signal non-inverting circuit 201 corresponds to the reference reset signal non-inverting circuit 101 shown in FIG. 1. The reference reset signal inverting circuit 202 corresponds to the reference reset signal inverting circuit 102 shown in FIG. 1. The INV circuit 204 corresponds to the INV circuit 104 shown in FIG. 1. The AND circuit 205 corresponds to the AND circuit 105 shown in FIG. 1. A signal line ROUT21 corresponds to the signal line ROUT11 shown in FIG. 1. A signal line ROUTZ22 corresponds to the signal line ROUTZ12 shown in FIG. 1. An external reset terminal 211 corresponds to the external reset terminal 111 shown in FIG. 1. Components different from those of the reset signal generating circuit 10 shown in FIG. 1 will be mainly described below.

An input terminal of the reference reset signal non-inverting circuit 203 is connected to the external reset terminal 211 of the semiconductor chip 2. An output terminal of the reference reset signal non-inverting circuit 203 and an input terminal (third node) of the AND circuit 205 are connected to each other via a signal line (third signal line) ROUT23. Note that, for convenience of explanation, a signal propagating through the signal line ROUT23 is also referred to as a signal ROUT23.

The reference reset signal non-inverting circuit 203 non-inverts the reference reset signal RESETZ and outputs the non-inverted signal. In other words, the reference reset signal non-inverting circuit 203 directly outputs the reference reset signal RESETZ. The signal line ROUT23 transmits the output signal of the reference reset signal non-inverting circuit 203 to the third input terminal (third node) of the AND circuit 205. The AND circuit 205 outputs the logical product of the signals received at the first to third input terminals as the reset signal IN_RESZ.

(Timing Diagram)

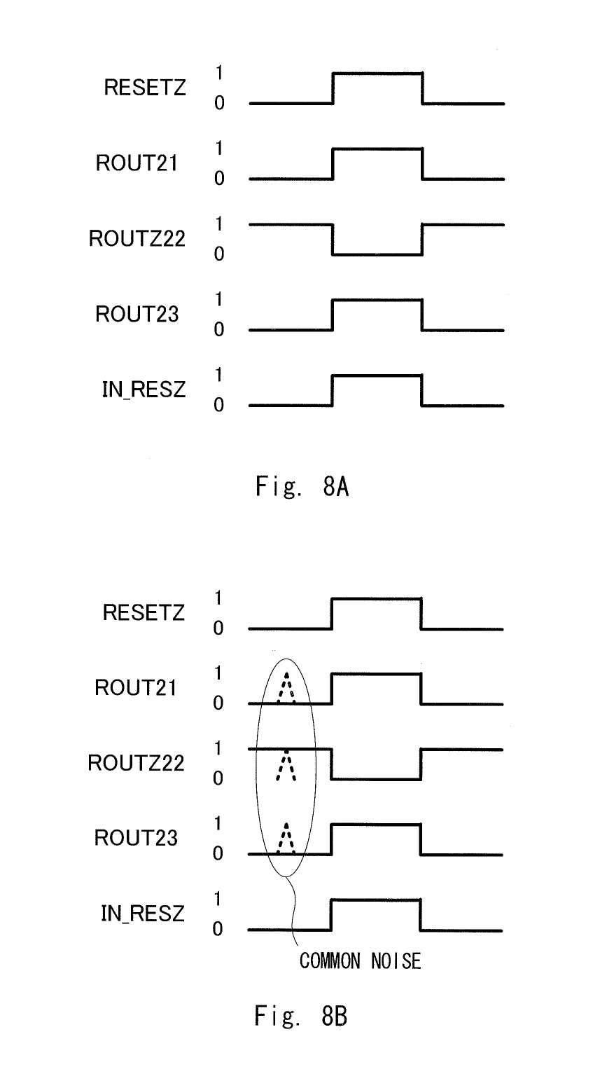

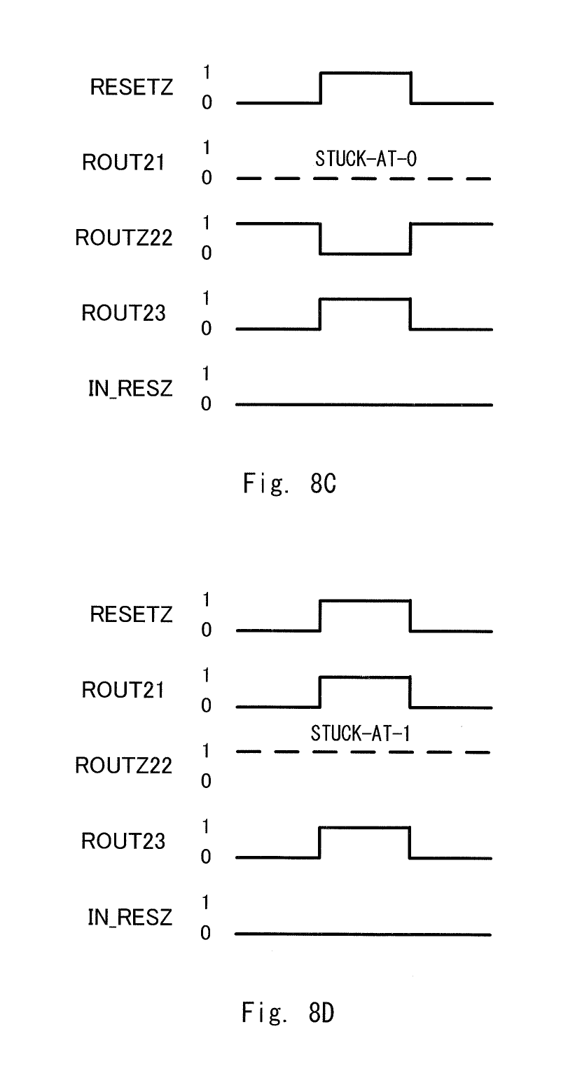

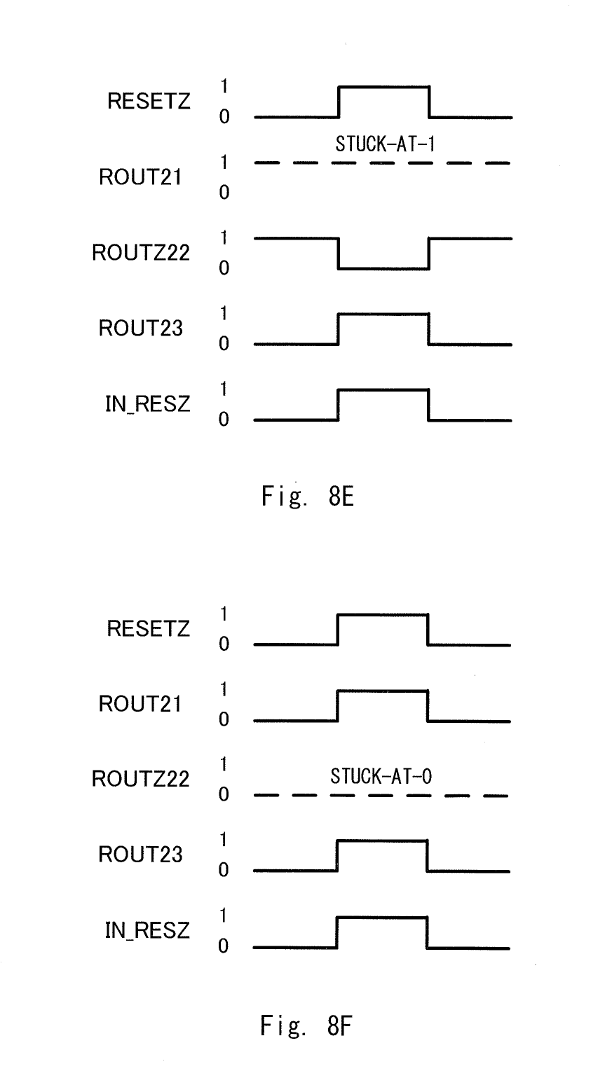

FIGS. 8A to 8F are timing diagrams each showing the operation of the reset signal generating circuit 20 shown in FIG. 7. In this case, conditions, such as a stuck-at fault, in the timing diagrams shown in FIGS. 8A to 8F are the same as conditions, such as a stuck-at fault, in the timing diagrams shown in FIGS. 6A to 6F. The operation of the reset signal generating circuit 20 when a stuck-at fault occurs in the signal line ROUT23 is similar to the operation when a stuck-at fault occurs in the signal line ROUT21, so the description thereof is omitted.

The operation of the reset signal generating circuit 20 shown in FIGS. 8A to 8F is the same as the operation of the reset signal generating circuit 10 shown in FIGS. 6A to 6F, so the description thereof is omitted.

As described above, the reset signal generating circuit 20 according to the second embodiment can provide the same advantageous effect as that of the reset signal generating circuit 10 illustrated in the first embodiment.

Furthermore, as compared with the case of the reset signal generating circuit 10 according to the first embodiment, the reset signal generating circuit 20 according to the second embodiment can prevent unintentional releasing of the reset signal IN_RESZ with high accuracy even when stuck-at faults occur in multiple signal lines.

For example, if stuck-at faults occur in two signal lines ROUT11 and ROUTZ12 in the reset signal generating circuit 10 shown in FIG. 1, there is no signal line that allows the reference reset signal RESETZ to be correctly transmitted. As a result, the reset signal IN_RESZ cannot be controlled by the reference reset signal RESETZ, and the reset signal IN_RESZ may be unintentionally released.

On the other hand, even when stuck-at faults occur in two signal lines ROUT21 and ROUTZ22 in the reset signal generating circuit 20 shown in FIG. 7, no stuck-at fault occurs in the signal line ROUT23, so that the reference reset signal RESETZ can be correctly transmitted through the signal line ROUT23. This enables control of the reset signal IN_RESZ by the reference reset signal RESETZ, and prevents unintentional releasing of the reset signal IN_RESZ.

In this regard, however, the reset signal generating circuit 10 shown in FIG. 1 is configured using a smaller number of signal lines than that of the reset signal generating circuit 20 shown in FIG. 7, and is thus excellent in suppressing an increase in the circuit size.

The second embodiment has described, by way of example, the case where an additional signal line for transmitting the non-inverted signal of the reference reset signal RESETZ is provided, but the present invention is not limited thereto. A signal line for transmitting the inverted signal of the reference reset signal RESETZ may be added. In this case, it is necessary to further provide an inverting circuit (second inverting circuit) that inverts and outputs the signal transmitted through the signal line.

### Third Embodiment

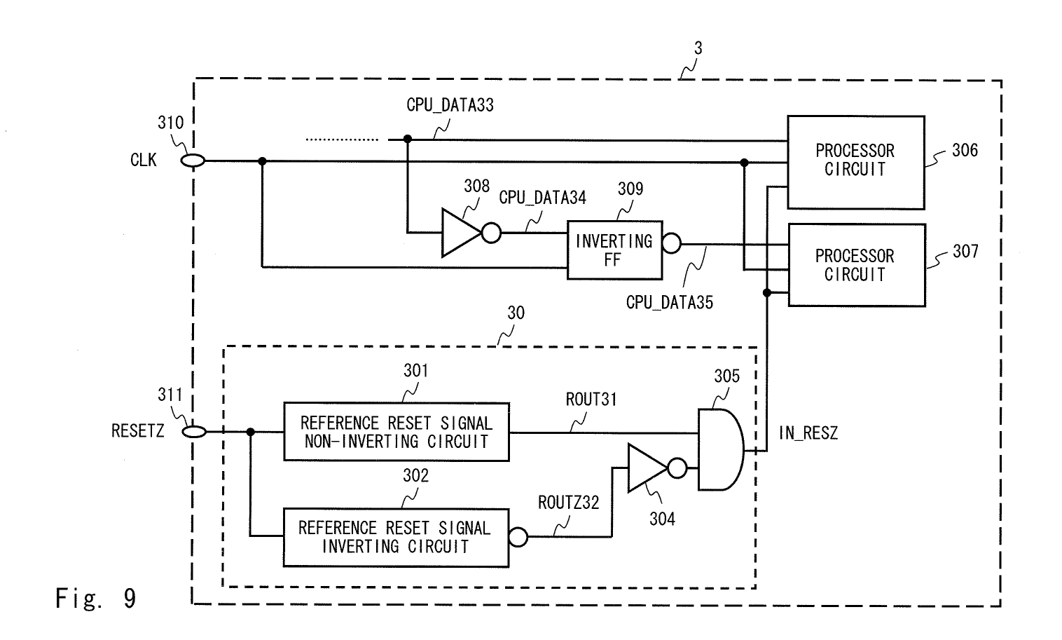

A third embodiment of the present invention describes an example of an application to a product of the reset signal generating circuit according to the present invention. FIG. 9 is a diagram showing a configuration example of a semiconductor chip (semiconductor integrated circuit) 3 including a reset signal generating circuit 30 according to the present invention.

The semiconductor chip 3 includes at least the reset signal generating circuit 30, a processor circuit (first processor) 306, a processor circuit (second processor) 307, an INV circuit 308, inverting flip-flop circuit (hereinafter referred to simply as “inverting FF”) 309. The processor circuit 306 and the processor circuit 307 have the same circuit configuration. In other words, the semiconductor chip 3 employs a redundant circuit configuration in which the two processor circuits 306 and 307 having the same configuration are provided.

The reset signal generating circuit 30 has the same circuit configuration as that of the reset signal generating circuit 10 shown in FIG. 1. That is, a reference reset signal non-inverting circuit 301 corresponds to the reference reset signal non-inverting circuit 101 shown in FIG. 1. A reference reset signal inverting circuit 302 corresponds to the reference reset signal inverting circuit 102 shown in FIG. 1. An INV circuit 304 corresponds to the INV circuit 104 shown in FIG. 1. The AND circuit 305 corresponds to the AND circuit 105 shown in FIG. 1. A signal line ROUT31 corresponds to the signal line ROUT11 shown in FIG. 1. A signal line ROUTZ32 corresponds to the signal line ROUTZ12 shown in FIG. 1.

The reset signal IN_RESZ generated by the reset signal generating circuit 30 is supplied to each of the processor circuit 306 and the processor circuit 307. That is, the initialization of each of the processor circuits 306 and 307 is controlled by the reset signal IN_RESZ.

A clock signal CLK is generated outside the semiconductor chip 3, for example, and is then supplied to an external clock terminal 310 of the semiconductor chip 3.

The processor circuit 306 loads data CPU_DATA 33 in synchronization with the clock signal CLK, and executes predetermined processing.

The INV circuit 308 inverts the data CPU_DATA 33 and outputs the inverted data as data CPU_DATA 34. The inverting FF 309 loads the data CPU_DATA 34 in synchronization with the clock signal CLK, and outputs the loaded data as data CPU_DATA 35. That is, the data CPU_DATA 35 is data obtained by delaying the data CPU_DATA 33 by one clock cycle.

The processor circuit 307 loads the data CPU_DATA 35 in synchronization with the clock signal CLK, and executes the predetermined processing. That is, the processor circuit 307 executes the same processing as that of the processor circuit 306 with a delay of one clock cycle.

In this manner, the processor circuit 307 operates with a delay from the processor circuit 306. The data supplied to the processor circuit 307 is inverted during propagation of the signal. This prevents the same malfunction from occurring in the processor circuits 306 and 307 even if noise or the like occurs. In general, such a countermeasure is taken only for a data line, and is not taken for a reset line and a clock line.

In practice, however, the length of the reset line is so long that the effect of noise cannot be neglected in many cases. Under such a circumstance, there is a possibility that the reset signal is unintentionally released due to the effect of noise or the like in the configuration in which the reset signal generating circuit of the present invention is not provided. If the reset signal is unintentionally released, the reset states of the processor circuits 306 and 307 are simultaneously released, which may make it impossible to detect the occurrence of malfunction.

On the other hand, as shown in FIG. 9, the configuration including the reset signal generating circuit 30 of the present invention can prevent unintentional releasing of the reset signal IN_RESZ, as described above, even if noise, a stuck-at fault, or the like occurs. This prevents malfunction from occurring in the processor circuits 306 and 307.

Note that the present invention is not limited to the embodiments described above, but can be modified as appropriate without departing from the scope of the present invention. The above embodiments have described, by way of example, the case where the control circuit is an AND circuit (105, 205, 305), but the configuration of the control circuit is not limited thereto. The control circuit can be appropriately changed to another circuit having the same function.

The above embodiments have described, by way of example, the case where the reset signal generating circuit includes two or three signal lines for transmitting the reference reset signal RESETZ, but the present invention is not limited thereto. The reset signal generating circuit may be appropriately changed to a configuration including four or more signal lines for transmitting the reference reset signal RESETZ. In this case, in order to prevent malfunction due to occurrence of common noise, the reset signal generating circuit needs to include at least one signal line for transmitting the non-inverted signal of the reference reset signal RESETZ and at least one signal line for transmitting the inverted signal of the reference reset signal RESETZ.

As described in the second embodiment, as the number of signal lines for transmitting the reference reset signal RESETZ increases, the probability of preventing unintentional releasing of the reset signal when stuck-at faults occur in multiple signal lines increases.

The reference reset signal non-inverting circuit and the reference reset signal inverting circuit, which are provided in the reset signal generating circuit according to the present invention, are preferably disposed near the external reset terminal. More preferably, the reference reset signal non-inverting circuit and the reference reset signal inverting circuit are preferably disposed to be adjacent to the external reset terminal.

If the reference reset signal generating circuit is provided in the semiconductor chip, the reference reset signal non-inverting circuit and the reference reset signal inverting circuit are preferably disposed near the reference reset signal generating circuit. More preferably, the reference reset signal non-inverting circuit and the reference reset signal inverting circuit are disposed to be adjacent to the reference reset signal generating circuit.

The inverting circuit (for example, the INV circuit 104 shown in FIG. 1) provided to the signal line for transmitting the inverted signal of the reference reset signal RESETZ is preferably disposed near the control circuit (for example, the AND circuit 105 shown in FIG. 1). More preferably, the inverting circuit provided to the signal line for transmitting the inverted signal of the reference reset signal RESETZ is disposed to be adjacent to the control circuit.

The above embodiments have described, by way of example, the case where the reset signal generating circuit includes the reference reset signal non-inverting circuit, but the configuration of the reset signal generating circuit is not limited thereto. The configuration may be changed to a configuration including no reference reset signal non-inverting circuit.

The above embodiments have described, by way of example, the case where the reset signal becomes active at L level, but the configuration of the reset signal is not limited thereto. The configuration may be changed into a configuration in which the reset signal becomes active at H level.

The first, second and third embodiments can be combined as desirable by one of ordinary skill in the art.

While the invention has been described in terms of several embodiments, those skilled in the art will recognize that the invention can be practiced with various modifications in the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A reset signal generating circuit comprising:
a first signal line that transmits a reference reset signal to a first node;
a second signal line that transmits an inverted signal of the reference reset signal to a second node;
a first inverting circuit that outputs the inverted signal of the signal transmitted to the second node; and
a control circuit that makes a reset signal active regardless of the reference reset signal, when a logical value of the signal transmitted to the first node does not match a logical value of the signal output from the first inverting circuit.

2. The reset signal generating circuit according to claim 1, wherein the control circuit outputs the reset signal having the same logical value as the logical value of the signal transmitted to the first node, when the logical value of the signal transmitted to the first node matches the logical value of the signal output from the first inverting circuit.

3. The reset signal generating circuit according to claim 1, further comprising a third signal line that transmits the reference reset signal to a third node,
wherein the control circuit makes the reset signal active regardless of the reference reset signal, when the logical value of the signal transmitted to the first node, the logical value of the signal transmitted to the third node, and the logical value of the signal output from the first inverting circuit do not match.

4. The reset signal generating circuit according to claim 1, further comprising:
a third signal line that transmits an inverted signal of the reference reset signal to a third node; and
a second inverting circuit that outputs the inverted signal of the signal transmitted to the third node,
wherein the control circuit makes the reset signal active regardless of the reference reset signal, when the logical value of the signal transmitted to the first node, the logical value of the signal output from the first inverting circuit, and the logical value of the signal output from the second inverting circuit do not match.

5. The reset signal generating circuit according to claim 4, wherein the second inverting circuit is disposed near the control circuit.

6. The reset signal generating circuit according to claim 1, wherein the first inverting circuit is disposed near the control circuit.

7. The reset signal generating circuit according to claim 1, wherein the control circuit is an AND circuit.

8. The reset signal generating circuit according to claim 1, further comprising an external reset terminal,
wherein the reference reset signal is supplied from an outside via the external reset terminal.

9. The reset signal generating circuit according to claim 8, further comprising a third inverting circuit that is disposed near the external reset terminal and outputs an inverted signal of the reference reset signal.

10. The reset signal generating circuit according to claim 1, further comprising a reference reset signal generating circuit that generates the reference reset signal.

11. The reset signal generating circuit according to claim 10, further comprising a third inverting circuit that is disposed near the reference reset signal generating circuit and outputs an inverted signal of the reference reset signal.

12. A semiconductor integrated circuit comprising:
a reset signal generating circuit according to claim 1, the reset signal generating circuit being configured to generate the reset signal; and
an internal circuit, initialization of the internal circuit being controlled by the reset signal.

13. A semiconductor integrated circuit comprising:
a signal generating circuit according to claim 1, the reset signal generating circuit being configured to generate the reset signal;
a first processor that loads data in synchronization with a clock signal, initialization of the first processor being controlled by the reset signal; and
a second processor that loads the data supplied with a delay of a predetermined clock cycle in synchronization with the clock signal, initialization of the second processor being controlled by the reset signal.
